(19) United States
(12) Patent Application Publication
(10) Pub. No.: US 2023/0073711 A1
(43) Pub. Date: Mar. 9, 2023

(54) SUBSTRATE SUPPORT ASSEMBLY AND PLASMA PROCESSING APPARATUS

(71) Applicant: Tokyo Electron Limited, Tokyo (JP)

(72) Inventors: Yuki AHIKO, Miyagi (JP); Yasuhisa KUDO, Miyagi (JP); Shingo KOIWA, Miyagi (JP)

(21) Appl. No.: 17/903,431

(22) Filed: Sep. 6, 2022

(30) Foreign Application Priority Data
Sep. 8, 2021 (JP) 2021-146247

(51) Int. Cl. H01J 37/32; H01L 21/683

(52) U.S. Cl. CPC H01J 37/32724; H01L 21/6833; H01J 2237/2007; H01J 2237/334

(57) ABSTRACT

A substrate support assembly includes: a base including a flow path for a temperature control medium; a substrate support including an electrode plate installed on the base and an electrostatic chuck installed on the electrode plate, and configured to support a substrate; a heater configured to heat the substrate; an elastic member installed between the base and the electrode plate, configured to separate the substrate support from the base, and configured to define a heat transfer space between the base and the electrode plate, a heat transfer gas being supplied into the heat transfer space; a tightening member configured to fasten the base and the electrode plate to each other, with the elastic member sandwiched and supported between the base and the electrode plate; and a heat insulator configured to prevent heat transfer between the base and the electrode plate via the elastic member.

### CROSS-REFERENCE TO RELATED APPLICATION

This application is based upon and claims the benefit of priority from Japanese Patent Application No. 2021-146247, filed on Sep. 8, 2021, the entire contents of which are incorporated herein by reference.

### TECHNICAL FIELD

The present disclosure relates to a substrate support assembly and a plasma processing apparatus.

### BACKGROUND

Patent Document 1 discloses a film forming apparatus that forms a film on the surface of a processing target by reacting a predetermined processing gas (raw material gas) in a processing container. This film forming apparatus is provided with a mounting table main body (substrate support) on which the processing target (e.g., a semiconductor wafer) is mounted upon film formation and with a base for supporting the mounting table main body. The mounting table main body includes a heating device (heater) for adjusting the temperature of the processing target, and the base includes a cooler (coolant passage) therein. Further, this film forming apparatus is provided with a heat insulating material between the mounting table main body and the base.

### PRIOR ART DOCUMENTS

### Patent Documents

Patent Document 1: Japanese Laid-Open Publication No. 2011-192661

### SUMMARY

According to one embodiment of the present disclosure, there is provided a substrate support assembly. The substrate support assembly includes: a base including a flow path for a temperature control medium formed therein; a substrate support including an electrode plate installed on the base and an electrostatic chuck installed on the electrode plate, and configured to support a substrate; a heater configured to heat the substrate; an elastic member installed between the base and the electrode plate, configured to separate the substrate support from the base, and configured to define a heat transfer space between the base and the electrode plate together with the base and the electrode plate, a heat transfer gas being supplied into the heat transfer space; a tightening member configured to fasten the base and the electrode plate to each other, with the elastic member sandwiched and supported between the base and the electrode plate; and a heat insulator configured to prevent heat transfer between the base and the electrode plate via the elastic member.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram schematically showing a configuration of a plasma processing system.

FIG. 2 is a vertical sectional view showing an outline of a configuration of a plasma processing apparatus.

FIG. 3 is an enlarged explanatory diagram showing a part of a substrate support assembly according to the present embodiment.

FIG. 4 is an explanatory diagram according to a first modification.

FIG. 5 is an explanatory diagram according to a second modification.

FIG. 6 is an explanatory diagram according to a third modification.

FIG. 7 is an explanatory diagram according to a fourth modification.

FIG. 8 is an explanatory diagram according to the fourth modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a process of manufacturing a semiconductor device, a semiconductor substrate (hereinafter also referred to as “substrate”) as a processing target is subjected to a plasma process such as etching. In the plasma process, a plasma is generated by exciting a processing gas, and the substrate is processed by the plasma.

A plasma processing apparatus that performs the plasma process generally includes a chamber, a substrate support assembly, and a radio frequency (RF) power supply. The RF power supply supplies radio frequency power (RF power) to, for example, an electrode (RF electrode) in the substrate support assembly. In one example, the RF power supply supplies source RF power for generating a plasma from the processing gas and bias RF power for drawing ions into the substrate. The substrate support assembly is provided in the chamber. The substrate support assembly has the RF electrode and an electrostatic chuck on the RF electrode.

By the way, recently, in the plasma process, adaptation of mask materials that is hard-to-etch, such as BSi, HfO, Ru, and WC has been studied in order to cope with further miniaturization of semiconductor devices. To adapt these hardly-etched materials, it is important to plasma-process the substrate in a high temperature region (e.g., 300 degrees C. or higher).

In order to perform the plasma process within the high temperature region, there is known a technique in which a seal material is sandwiched and supported between a substrate support and a base, and a heat transfer gas such as a helium gas is supplied to the space surrounded by them. The seal material may generally use an O-ring made of an elastomer such as rubber. However, the elastomeric O-ring has low heat resistance and is difficult to respond the plasma process within the high temperature region. Therefore, for example, it is conceivable to use an O-ring or C-ring made of a metal such as aluminum or SUS as the seal material. In that case, since the thermal conductivity of a metal is extremely higher than that of rubber, the seal material becomes a heat path, and it is not possible to efficiently raise the surface temperature of the substrate support. In turn, there is a concern that the substrate cannot be sufficiently heated, or that high power is required to heat the substrate.

The technique according to the present disclosure has been conceived in view of the above circumstances, and aims to efficiently raise the surface temperature of a substrate support and improve the temperature controllability within a high temperature region in a substrate processing apparatus that performs a plasma process, or the like on a substrate as a processing target. Hereinafter, a plasma processing system according to one embodiment and a plasma processing method including an etching method according to the present embodiment will be described with reference to the drawings. In addition, in the present specification and the accompanying drawings, the elements having substantially the same functional configuration will be denoted by the same reference numerals, and redundant explanations will be omitted.

### Plasma Processing System

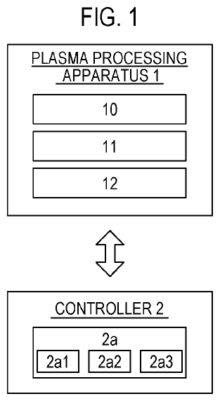

First, the plasma processing system according to one embodiment will be described with reference to FIG. 1. FIG. 1 is an explanatory diagram schematically showing a configuration of the plasma processing system.

In one embodiment, the plasma processing system includes a plasma processing apparatus 1 and a controller 2. The plasma processing apparatus 1 includes a plasma processing chamber 10, a substrate support assembly 11, and a plasma generator 12. The plasma processing chamber 10 has a plasma processing space. Further, the plasma processing chamber 10 has at least one gas supply port for supplying at least one processing gas into the plasma processing space, and at least one gas discharge port for discharging the gas from the plasma processing space. The gas supply port is connected to a gas supplier 20 described below, and the gas discharge port is connected to an exhaust system 40 described below. The substrate support assembly 11 is arranged in the plasma processing space and has a substrate support surface for supporting a substrate.

The plasma generator 12 is configured to generate a plasma from at least one processing gas supplied in the plasma processing space. The plasma generated in the plasma processing space may be capacitively coupled plasma (CCP), inductively coupled plasma (ICP), electron-cyclotron-resonance (ECR) plasma, helicon wave excitation plasma (HWP), surface wave plasma (SWP), or the like. Further, various types of plasma generators, including an alternating current (AC) plasma generator and a direct current (DC) plasma generator, may be used. In one embodiment, an AC signal (AC power) used in the AC plasma generator has a frequency in a range of 100 kHz to 10 GHz. Therefore, the AC signal includes a radio frequency (RF) signal and a microwave signal. In one embodiment, the RF signal has a frequency in a range of 200 kHz to 150 MHz.

The controller 2 processes computer-executable instructions that cause the plasma processing apparatus 1 to execute various steps described in the present disclosure. The controller 2 may be configured to control each element of the plasma processing apparatus 1 so as to execute various steps described herein. In one embodiment, a part or all of the controller 2 may be included in the plasma processing apparatus 1. The controller 2 may include, for example, a computer 2a. The computer 2a may include, for example, a central processing unit (CPU) 2a1, a storage 2a2, and a communication interface 2a3. The central processing unit 2a1 may be configured to perform various control operations based on programs stored in the storage 2a2. The storage 2a2 may include a computer readable storage medium such as random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Plasma Processing Apparatus

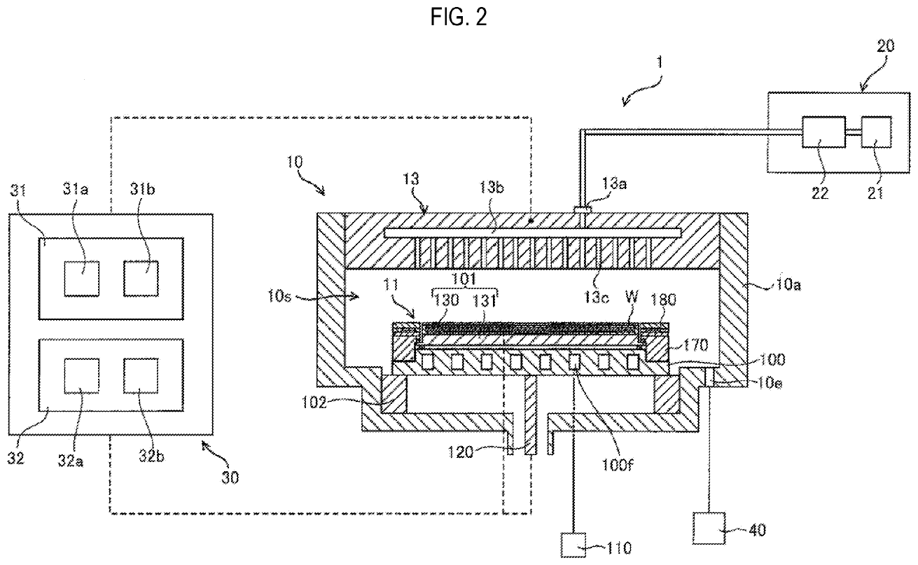

Hereinafter, a configuration example of a capacitively coupled plasma processing apparatus as an example of the plasma processing apparatus 1 will be described with reference to FIG. 2. FIG. 2 is a vertical sectional view showing an outline of the configuration of the plasma processing apparatus 1. The plasma processing apparatus 1 of the present embodiment performs a plasma process on a substrate (wafer) W, but the substrate W as a plasma processing target is not limited to the wafer.

The capacitively coupled plasma processing apparatus 1 includes the plasma processing chamber 10, the gas supplier 20, a power supply 30, and the exhaust system 40. Further, the plasma processing apparatus 1 includes the substrate support assembly 11 and a gas introducer. The gas introducer is configured to introduce at least one processing gas into the plasma processing chamber 10. The gas introducer includes a shower head 13. The substrate support assembly 11 is arranged in the plasma processing chamber 10. The shower head 13 is arranged above the substrate support assembly 11. In one embodiment, the shower head 13 constitutes at least a portion of the ceiling of the plasma processing chamber 10. The plasma processing chamber 10 has a plasma processing space 10s defined by the shower head 13, a sidewall 10a of the plasma processing chamber 10, and the substrate support assembly 11. The sidewall 10a is grounded. The shower head 13 and the substrate support assembly 11 are electrically insulated from a housing of the plasma processing chamber 10.

The shower head 13 is configured to introduce at least one processing gas from the gas supplier 20 into the plasma processing space 10s. The shower head 13 has at least one gas supply port 13a, at least one gas diffusion chamber 13b, and plural gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. In addition to the shower head 13, the gas introducer may include one or plural side gas injectors (SGI) provided in one or plural openings formed in the sidewall 10a.

The gas supplier 20 may include at least one gas source 21 and at least one flow rate controller 22. In one embodiment, the gas supplier 20 is configured to supply at least one processing gas from each corresponding gas source 21 to the shower head 13 via each corresponding flow rate controller 22. Each flow rate controller 22 may include, for example, a mass flow controller or a pressure-controlled flow rate controller. Further, the gas supplier 20 may include at least one flow rate modulation device that modulates or pulses the flow rate of at least one processing gas.

The power supply 30 includes an RF power supply 31 coupled to the plasma processing chamber 10 via at least one impedance matching circuit. The power supply 30 is an example of the plasma generator 12. The RF power supply 31 is configured to supply at least one RF signal (RF power) such as a source RF signal and a bias RF signal to a conductive member of the substrate support assembly 11 and/or the conductive member of the shower head 13. Thereby, a plasma is generated from at least one processing gas supplied to the plasma processing space 10s. Further, when the bias RF signal is supplied to the conductive member of the substrate support assembly 11, a bias potential occurs in the substrate W, thus enabling ion components of the generated plasma to be drawn into the substrate W.

In one embodiment, the RF power supply 31 includes a first RF generator 31a and a second RF generator 31b. The first RF generator 31a is coupled to the conductive member of the substrate support assembly 11 and/or the conductive member of the shower head 13 via at least one impedance matching circuit, and is configured to generate a source RF signal (source RF power) for plasma generation. In one embodiment, the source RF signal has a frequency in a range of 13 MHz to 150 MHz. In one embodiment, the first RF generator 31a may be configured to generate plural source RF signals with different frequencies. The generated one or plural source RF signals are supplied to the conductive member of the substrate support assembly 11 and/or the conductive member of the shower head 13. The second RF generator 31b is coupled to the conductive member of the substrate support assembly 11 via at least one impedance matching circuit, and is configured to generate a bias RF signal (bias RF power). In one embodiment, the bias RF signal has a lower frequency than the source RF signal. In one embodiment, the bias RF signal has a frequency in a range of 400 kHz to 13.56 MHz. In one embodiment, the second RF generator 31b may be configured to generate plural bias RF signals with different frequencies. The generated one or plural bias RF signals are supplied to the conductive member of the substrate support assembly 11. Further, in various embodiments, at least one of the source RF signal and the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is connected to the conductive member of the substrate support assembly 11, and is configured to generate a first DC signal. The generated first DC signal is applied to the conductive member of the substrate support assembly 11. In one embodiment, the first DC signal may be applied to another electrode such as an electrode in an electrostatic chuck. In one embodiment, the second DC generator 32b is connected to the conductive member of the shower head 13, and is configured to generate a second DC signal. The generated second DC signal is applied to the conductive member of the shower head 13. In various embodiments, the first and second DC signals may be pulsed. In addition, the first and second DC generators 32a and 32b may be provided in addition to the RF power supply 31, and the first DC generator 32a may be provided in place of the second RF generator 31b.

The exhaust system 40 may be connected to, for example, a gas outlet 10e provided at the bottom of the plasma processing chamber 10. The exhaust system 40 may include a pressure regulating valve and a vacuum pump. The pressure in the plasma processing space 10s is regulated by the pressure regulating valve. The vacuum pump may include a turbo molecular pump, a dry pump or a combination thereof.

### Substrate Support Assembly

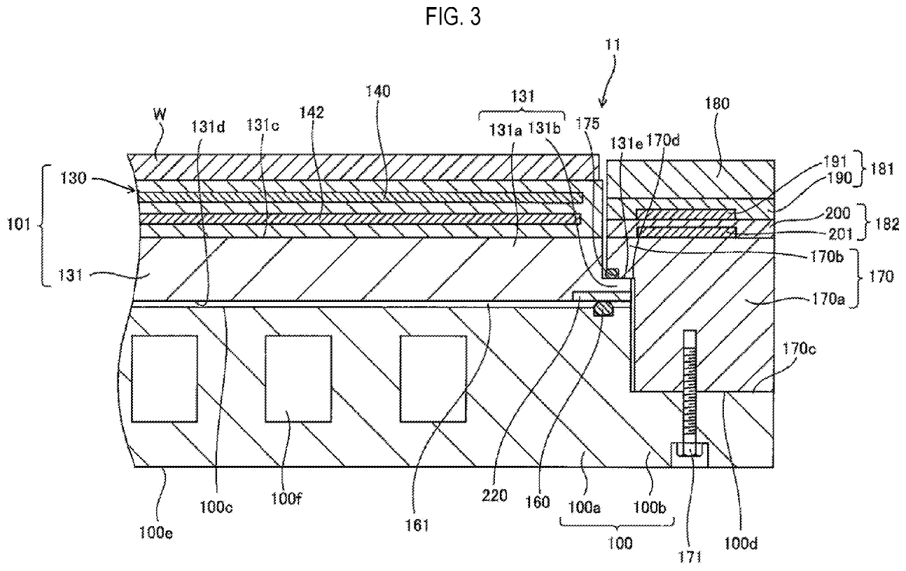

Next, the substrate support assembly 11 described above and the plasma processing apparatus 1 including the substrate support assembly 11 will be described with reference to FIGS. 2 and 3. FIG. 3 is an enlarged explanatory diagram showing a part of the substrate support assembly 11.

The substrate support assembly 11 for supporting the substrate W includes a base 100 and a substrate support 101. The base 100 is supported by a support member 102 extending from the bottom of the plasma processing chamber 10. The support member 102 is an insulating member and is made of, for example, an aluminum oxide (alumina) Further, the support member 102 has a substantially circular cylindrical shape.

The base 100 is made of a conductive metal, for example, aluminum. The base 100 has a substantially disk shape. The base 100 has a central portion 100a and a peripheral edge portion 100b. The central portion 100a has a substantially disk shape. The central portion 100a provides a first upper surface 100c of the base 100.

The peripheral edge portion 100b has a substantially annular shape in a plan view. The peripheral edge portion 100b is continuous with the central portion 100a and extends circumferentially outside the central portion 100a in the radial direction. The peripheral edge portion 100b provides a second upper surface 100d of the base 100. The second upper surface 100d is located lower than the first upper surface 100c in the vertical direction. Further, the peripheral edge portion 100b provides a lower surface 100e of the base 100 together with the central portion 100a.

A flow path 100f for a temperature control medium is formed in the base 100. The flow path 100f extends in the base 100, for example, in a spiral shape. A temperature control medium is supplied to the flow path 100f by a chiller unit 110 provided outside the plasma processing chamber 10. The temperature control medium supplied to the flow path 100f is a liquid that belongs to the operating temperature range of the plasma processing apparatus 1, for example, the temperature zone of 20 degrees C. or higher and 250 degrees C. or lower. Alternatively, the temperature control medium may be a coolant that absorbs heat for cooling by vaporization thereof, and may be, for example, a hydrofluorocarbon-based coolant.

A feeder 120 is connected to the base 100. The feeder 120 is a feeding rod and is connected to the lower surface 100e of the base 100. The feeder 120 is made of aluminum or an aluminum alloy. The feeder 120 is electrically connected to the RF power supply 31 of the aforementioned power supply 30.

The substrate support 101 is installed on the first upper surface 100c of the base 100. The substrate support 101 includes an electrostatic chuck 130 and an electrode plate 131. The electrode plate 131 forms a lower electrode and is installed on the base 100. The electrode plate 131 has conductivity. The electrode plate 131 may be made of, for example, ceramics obtained by imparting conductivity to an aluminum nitride or a silicon carbide, or may be made of a metal (e.g., titanium).

The electrode plate 131 has a substantially disk shape, and has a central portion 131a and a peripheral edge portion 131b. The central portion 131a has a substantially disk shape. The central portion 131a provides an upper surface 131c of the electrode plate 131. The upper surface 131c is a substantially circular surface. The peripheral edge portion 131b is continuous with the central portion 131a and extends circumferentially outside the central portion 131a in the radial direction. In one embodiment, the peripheral edge portion 131b provides a lower surface 131d of the electrode plate 131 together with the central portion 131a. Further, the peripheral edge portion 131b provides an upper surface 131e. The upper surface 131e is a band-shaped surface, and extends circumferentially outside the upper surface 131c in the radial direction. Further, the upper surface 131e is closer to the lower surface 131d than the upper surface 131c in the vertical direction.

The electrostatic chuck 130 is installed on the electrode plate 131, and is coupled to the electrode plate 131 by, for example, metal bonding using a metal interposed between the electrostatic chuck 130 and the electrode plate 131. The electrostatic chuck 130 has a substantially disk shape and may be made of ceramics. The ceramics forming the electrostatic chuck 130 may use ceramics having a volume resistivity of 1×10¹⁵ Ω·cm or more in a temperature range of room temperature (e.g., 20 degrees C.) or higher and 400 degrees C. or lower. For example, such ceramics may use an aluminum oxide (alumina) which is a metal oxide. With the ceramic electrostatic chuck 130 having such a volume resistivity, a sufficient attraction force is exerted even within a high temperature region exceeding 200 degrees C. In addition, the electrostatic chuck 130 may be made of dielectrics, for example, polyimide, other than ceramics.

The electrostatic chuck 130 includes an attraction electrode 140 and a heater 142 embedded therein. The attraction electrode 140 is an electrode film, and the direct current (DC) power supply 32 is electrically connected to the attraction electrode 140. When a DC voltage from the DC power supply 32 is applied to the attraction electrode 140, an electrostatic force is generated, and the substrate W is held by the electrostatic force. The present embodiment exemplifies a Coulomb type electrostatic chuck, but is not limited thereto and may employ a Johnson-Rahbeck type electrostatic chuck. In this case, the ceramics forming the electrostatic chuck 130 may use one having a volume resistivity of 1×10⁸ to 1×10¹¹ Ω·cm in a temperature range of room temperature or higher and 400 degrees C. or lower, for example, a metal nitride such as an aluminum nitride.

The heater 142 is located below the attraction electrode 140. The heater 142 is electrically connected to, for example, a heater power supply (not shown) outside the apparatus. A voltage from the heater power supply is applied to the heater 142, and the substrate W is controlled to a desired temperature by the heater 142.

An elastic member 160 is provided between the electrode plate 131 (the substrate support 101) and the base 100. The elastic member 160 is in contact with the upper surface 100c of the base 100 and a heat insulator 220 placed on the lower surface 131d of the electrode plate 131. The elastic member 160 separates the substrate support 101 upward from the base 100. The elastic member 160 is, for example, an O-ring. The elastic member 160 is configured to have a thermal resistivity higher than the thermal resistivity of a heat transfer space 161 at the time when a He gas is supplied to the heat transfer space 161. Further, the elastic member 160 is required to have low thermal conductivity and high heat resistance. Such an elastic member 160 may be made of an elastomer or a metal. The elastomeric elastic member 160 may be made of perfluoro elastomer (FFKM), vinylidenefluoride-based fluororubber (FKM), silicone, or the like. Further, the metallic elastic member 160 may be made of aluminum, SUS, a Ni-based superalloy, or the like.

A space surrounded by the base 100, the substrate support 101, and the elastic member 160 is the heat transfer space 161 into which a heat transfer gas is supplied. The heat transfer space 161 is sealed by the elastic member 160 between the base 100 and the substrate support 101. The heat transfer space 161 is configured to receive the heat transfer gas, for example, a He gas supplied from the gas supplier (not shown) provided outside the plasma processing chamber 10.

The heat insulator 220 is provided on the top of the elastic member 160 between the electrode plate 131 (the substrate support 101) and the base 100. The heat insulator 220 has a substantially annular plate shape, and is a member or space having a smaller thermal conductivity than the electrode plate 131. That is, the heat insulator 220 is a member or space that thermally shields between the elastic member 160 and the lower surface 131d of the electrode plate 131. The heat insulator 220 is installed on the peripheral edge portion 131b of the lower surface 131d of the electrode plate 131 in the circumferential direction. More specifically, the heat insulator 220 is installed at least within a range where the elastic member 160 and the lower surface 131d come into contact with each other with the absence of the heat insulator 220. The heat insulator 220 may be installed on the lower surface 131d of the electrode plate 131 over the central portion 131a and the peripheral edge portion 131b, for example.

The heat insulator 220 may be configured as a member made of a low thermal conductivity metal, ceramics, resin, or the like. Alternatively, the heat insulator 220 may be configured as a pressure-reduced space defined in a predetermined region. In either case, the thermal conductivity of the heat insulator 220 may be, for example, 20 W/mK or less. Such a range of the thermal conductivity may prevent the elastic member 160 from being heated to a heat-resistant temperature or higher even during a substrate process within a high temperature region and even when the elastomeric elastic member 160 is used. Further, since the transmission quantity of heat through the elastic member 160 may be reduced even when the metallic elastic member 160 is used, it is possible to efficiently raise the surface temperature of the substrate support assembly.

In the case of configuring the heat insulator 220 as a member, the heat insulator 220 may be made of, for example, a low thermal conductivity metal-containing material or ceramics. Examples of the low thermal conductivity metal-containing material include pure titanium, 64 titanium (Ti-6Al-4V), a titanium-containing material such as aluminum titanate, stainless steel, and the like. Further, examples of the ceramics include alumina, yttria, zirconia, glass ceramics, and the like. Further, the heat insulator 220 may be made of a polymer material as long as it has a heat resistance of 300 degrees C. or higher. Such a polymer material is polyimide, or the like.

Further, in the case of configuring the heat insulator 220 as a member, the heat insulator 220 may be a surface-treated porous material. For example, the heat insulator 220 may include a porous material and a coating material covering the surface of the porous material, or may be a porous material having a sealing layer that seals the surface of the porous material. When sealing the surface of the porous material, the thickness of the sealing layer may be 1 mm or more from the surface of the porous material, or may be 2 mm or more. Examples of the porous material include porous alumina, porous titanium, and porous zirconia. Examples of the coating material or the sealing material include a metal material such as aluminum or titanium, and ethyl silicate. A surface treatment may be performed by, for example, cold spraying, impregnation, or the like.

In the case of configuring the heat insulator 220 as a member, the heat insulator 220 may be integrally molded with the electrode plate 131 by, for example, a hot press, or the like. Further, a stepped portion may be formed on the outer edge of the lower surface 131d of the electrode plate 131 in the circumferential direction, and the heat insulator 220 may be secured to the stepped portion by any method such as welding, spraying, bonding, gluing, or bolting. The heat insulator 220 may be positioned so as to be embedded in the electrode plate 131, or may be positioned so as to be installed to the surface (here, the lower surface 131d) of the electrode plate 131.

Further, in the case of configuring the heat insulator 220 as a pressure-reduced space, for example, it may be formed by defining a space extending in the circumferential direction in the lower surface 131d of the electrode plate 131, and reducing the pressure in the space. In addition, when configuring the pressure-reduced space as the heat insulator 220, the pressure-reduced space may have a single-layer structure or a multi-layer structure. The multi-layer structure will further improve thermal insulation.

The substrate support assembly 11 further includes a tightening member 170. The tightening member 170 is configured to sandwich and support the elastic member 160 between the base 100 and the electrode plate 131. The tightening member 170 may be made of a material having a low thermal conductivity, for example, titanium or a titanium-containing material such as a titanium alloy, in order to reduce heat conduction from the tightening member 170 between the electrode plate 131 and the base 100.

The tightening member 170 has a cylindrical portion 170a and an annular portion 170b. The cylindrical portion 170a has a substantially circular cylindrical shape, and provides a first lower surface 170c at the lower end thereof. The annular portion 170b has a substantially annular plate shape, and extends radially inward from the cylindrical portion 170a so as to be continuous with the inner edge of a top portion of the cylindrical portion 170a. The annular portion 170b provides a second lower surface 170d.

The tightening member 170 is arranged such that the first lower surface 170c is in contact with the upper surface 100d of the base 100 and the second lower surface 170d is in contact with the upper surface 131e of the electrode plate 131. Further, the tightening member 170 may be fixed to, for example, the peripheral edge portion 100b of the base 100 by a bolt 171. In this case, the crushing amount (compression amount) of the elastic member 160 is adjusted by adjusting the tightening torque of the bolt 171 with respect to the tightening member 170.

In addition, an elastic member 175 may be provided between the second lower surface 170d of the tightening member 170 and the upper surface 131e of the electrode plate 131. The elastic member 175 may be an O-ring, and prevents particles (e.g., metal powder), which may be generated by friction between the second lower surface 170d and the upper surface 131e, from moving to the plasma processing space 10s.

Further, although not shown here, a heat insulating space for thermal insulation may be defined between the first lower surface 170c of the tightening member 170 and the upper surface 100d of the base 100. This heat insulating space may be configured to be reduced in pressure by the evacuation of the plasma processing chamber 10.

An edge ring 180 and an edge ring electrostatic chuck 181 are provided on the upper surface side of the tightening member 170. Further, in addition to the edge ring 180 and the edge ring electrostatic chuck 181, an edge ring temperature controller 182 may be provided on the upper surface side of the tightening member 170. The edge ring 180, the edge ring electrostatic chuck 181, and the edge ring temperature controller 182 may be stacked in the named order from above to below. The edge ring 180 is arranged so as to surround the substrate W mounted on the substrate support 101 (electrostatic chuck 130). The edge ring 180 improves the uniformity of a plasma process on the substrate W.

The edge ring electrostatic chuck 181 has the same configuration as the electrostatic chuck 130. That is, the edge ring electrostatic chuck 181 is configured such that an attraction electrode 191 is provided inside a base layer 190. The base layer 190 has a substantially annular shape in a plan view. The base layer 190 may be made of, for example, the same material as the electrostatic chuck 130. Further, the base layer 190 may be selected according to an electrostatic force (Coulomb force or Johnson-Rahbeck force) for attracting and holding the substrate W.

The attraction electrode 191 is a substantially annular electrode film having conductivity. A DC power supply outside the apparatus is electrically connected to the attraction electrode 191. When a DC voltage from the DC power supply is applied to the attraction electrode 191, the edge ring electrostatic chuck 181 generates an electrostatic force such as Coulomb force or Johnson-Rahbeck force, and holds the edge ring 180 by the electrostatic force. In addition, the attraction electrode 191 may include plural electrodes configured to generate different potentials. In one example, the attraction electrode 191 may include an annular-shaped inner electrode arranged in the central portion 131a of the electrode plate 131 and an annular-shaped outer electrode arranged outside the inner electrode.

The edge ring temperature controller 182 is configured such that a heater electrode 201 is installed inside a base layer 200. The base layer 200 has a substantially annular shape in a plan view. The base layer 200 may be made of the same material as the base layer 190.

The heater electrode 201 is electrically connected to a heater power supply outside the apparatus. When a voltage from the heater power supply is applied to the heater electrode 201, the edge ring 180 is controlled to a desired temperature.

In addition, the substrate support assembly 11 includes a gas line (not shown) for supplying the heat transfer gas (e.g., He gas) between the substrate W and the electrostatic chuck 130. A gas diffusion space (not shown) in which the heat transfer gas diffuses is defined between the substrate W and the electrostatic chuck 130.

### Plasma Processing Method

Next, a plasma process performed by using the plasma processing system configured as described above will be described. For example, an etching process or a film forming process is performed as the plasma process.

First, the substrate W is loaded to the inside of the plasma processing chamber 10, and the substrate W is mounted on the electrostatic chuck 130. Thereafter, by applying a DC voltage to the attraction electrode 140 of the electrostatic chuck 130, the substrate W is electrostatically attracted and held by the electrostatic chuck 130 by the Coulomb force or Johnson-Rahbeck force. Further, after the substrate W is loaded, the inside of the plasma processing chamber 10 is reduced in pressure to a desired degree of vacuum by the exhaust system 40.

Subsequently, a processing gas is supplied from the gas supplier 20 to the plasma processing space 10s via the shower head 13. Further, the source RF power for plasma generation is supplied to the electrode plate 131 by the RF power supply 31. Then, the processing gas is excited to generate a plasma. At this time, the bias RF power for drawing ions may be supplied by the RF power supply 31. Then, the substrate W is subjected to a plasma process by the action of the generated plasma.

### Effects of Technique of the Present Disclosure

According to the above embodiment, in the configuration of the substrate support assembly 11, the heat insulator 220 is installed between the electrode plate 131 and the elastic member 160. Therefore, even when the elastomeric elastic member 160 having a relatively low heat resistance is used, damage to or deterioration of the elastic member 160 may be prevented during a substrate process within a high temperature region (e.g., 300 degrees C. or higher).

Further, even when the metallic elastic member 160 having a high thermal conductivity is used, it is possible to reduce the transmission quantity of heat through the elastic member 160, and in turn, it is possible to efficiently raise the surface temperature of the substrate support assembly 11. That is, since the output of the heater 142 required to raise the temperature of the substrate W or to keep the substrate W warm is reduced, the improved energy efficiency or the reduced energy consumption may be achieved.

In addition, by providing the heat insulator 220 between the electrode plate 131 and the elastic member 160, the local temperature drop around the elastic member 160 is reduced. This may improve the in-plane uniformity of the surface temperature of the electrostatic chuck 130, and consequently, improve the in-plane uniformity of the temperature of the substrate W.

The embodiments disclosed herein should be considered to be exemplary and not limitative in all respects. The above-described embodiments may be omitted, replaced, or modified in various embodiments without departing from the scope of the appended claims and their gist.

### MODIFICATIONS OF THE PRESENT DISCLOSURE

Although the configuration of the substrate support assembly 11 according to the above embodiment in which the heat insulator 220 is installed between the electrode plate 131 and the elastic member 160 has been shown and described, the scope of the present disclosure is not limited thereto, and various other configurations of the heat insulator 220 may be considered. Hence, in the following, modifications of the present disclosure will be described with reference to the drawings. In addition, in the following modifications, the elements having the same functional configuration as those in the above embodiment are shown and denoted by the same reference numerals, and the description thereof may be omitted.

### First Modification

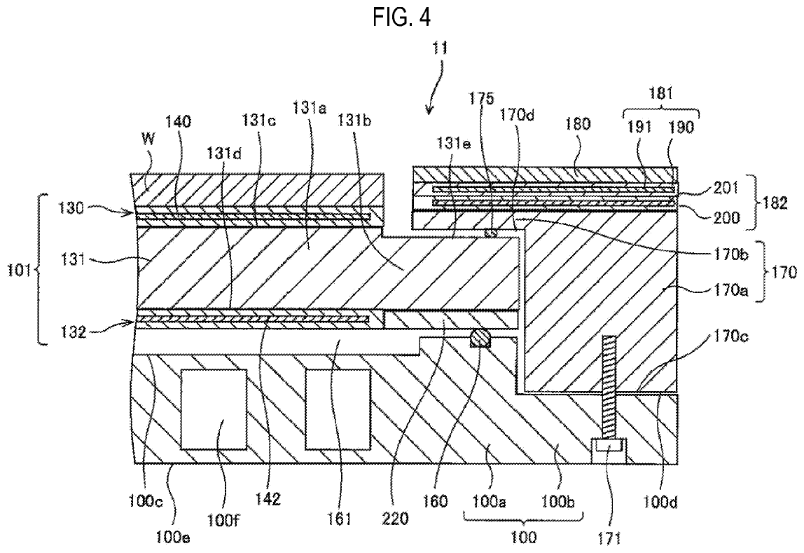

FIG. 4 is an explanatory diagram according to a first modification, showing a part of the substrate support assembly 11 in an enlarged scale.

As shown in FIG. 4, in a configuration according to the first modification, the substrate support 101 includes the electrostatic chuck 130, the electrode plate 131, and a temperature controller 132, which are arranged in the named order from above. Similar to the electrostatic chuck 130, the temperature controller 132 is coupled to the electrode plate 131 (lower surface 131d) by metal bonding using a metal interposed between the temperature controller 132 and the electrode plate 131. Similar to the electrostatic chuck 130, the temperature controller 132 has a substantially disk shape and is made of ceramics.

In this modification, the attraction electrode 140 is embedded in the electrostatic chuck 130, and the heater 142 is embedded in the temperature controller 132. That is, in the substrate support 101, the attraction electrode 140 and the heater 142 are installed so as to be vertically spaced apart from each other with the electrode plate 131 interposed therebetween. The heat insulator 220 is provided outside the temperature controller 132 in the circumferential direction.

With the configuration according to this modification, there are the following advantages in addition to the effects described in the above embodiment. That is, the substrate support 101 is configured such that the electrostatic chuck 130 having the attraction electrode 140 and the temperature controller 132 having the heater 142 are vertically separated from each other and the electrode plate 131 is sandwiched between the electrostatic chuck 130 and the temperature controller 132. By separating the attraction electrode 140 and the heater 142 from each other in this way, it is possible to reduce the thickness of the electrostatic chuck 130, and consequently, to prevent the loss of RF power on the low frequency side such as 400 kHz. Further, it is possible to reduce the potential difference between the substrate W and the electrode plate 131, which may prevent abnormal discharge on the rear surface of the substrate W.

### Second Modification

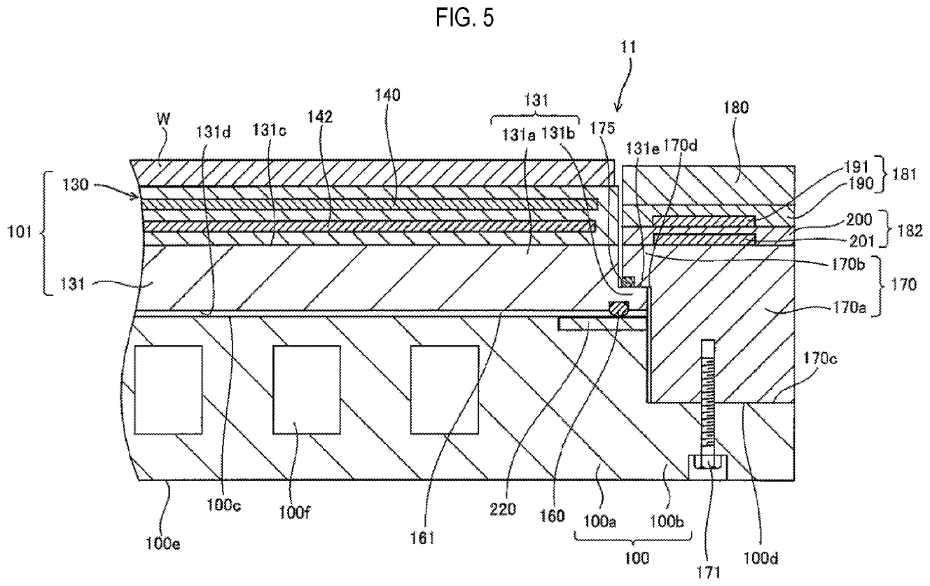

FIG. 5 is an explanatory diagram according to a second modification, showing a part of the substrate support assembly 11 in an enlarged scale.

As shown in FIG. 5, in a configuration according to the second modification, the heat insulator 220 is installed below the elastic member 160.

In the configuration according to this modification, the elastic member 160 may be made of a metal rather than an elastomer since the electrode plate 131 and the elastic member 160 are in contact with each other. With this modification, since thermal insulation by the heat insulator 220 is obtained between the base 100 and the elastic member 160, it is possible to reduce the transmission quantity of heat through the elastic member 160 as in the above embodiment, and consequently, to efficiently raise the surface temperature of the substrate support assembly 11. That is, since the output of the heater 142 required to raise the temperature of the substrate W or to keep the substrate W warm is reduced, the improved energy efficiency or the reduced energy consumption may be achieved.

### Third Modification

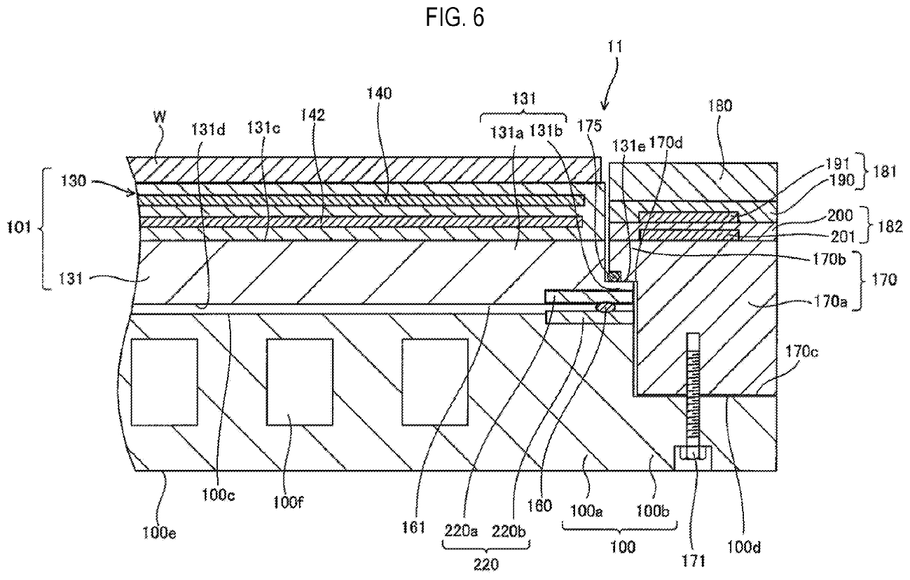

FIG. 6 is an explanatory diagram according to a third modification, showing a part of the substrate support assembly 11 in an enlarged scale.

As shown in FIG. 6, in a configuration according to the third modification, two heat insulators 220 (here, a first heat insulator 220a and a second heat insulator 220b) are installed on both the top and bottom of the elastic member 160. With the configuration according to this modification, it is possible to realize a further improvement in the thermal insulation performance around the elastic member 160. That is, when the electrostatic chuck 130 is required to have a high temperature, it is possible to efficiently raise the temperature of the electrostatic chuck 130 to a temperature equal to or higher than the heat resistant temperature of the elastic member 160.

### Fourth Modification

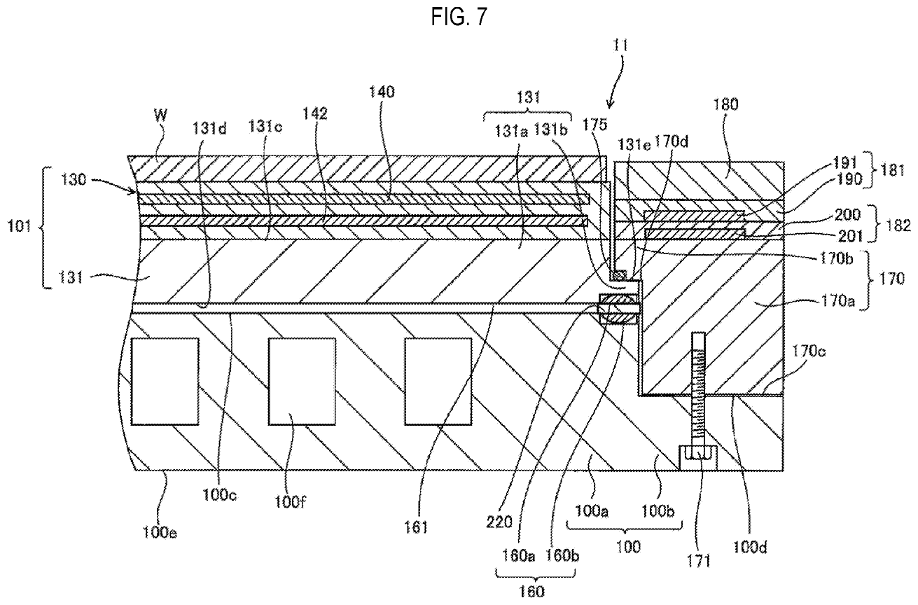

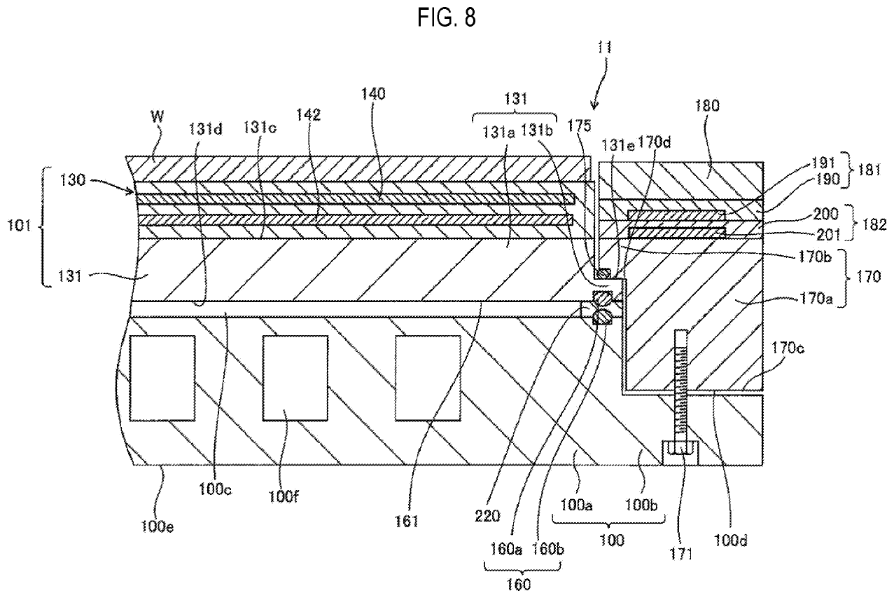

FIGS. 7 and 8 are explanatory diagrams according to a fourth modification, showing a part of the substrate support assembly 11 in an enlarged scale.

As shown in FIGS. 7 and 8, in a configuration according to the fourth modification, a first elastic member 160a and a second elastic member 160b are arranged above and below the heat insulator 220, respectively, between the base 100 and the electrode plate 131 so as to sandwich the heat insulator 220 therebetween. More specifically, as shown in FIG. 7, the first elastic member 160a, the second elastic member 160b, and the heat insulator 220 may be configured as an integral member. Alternatively, as shown in FIG. 8, the first elastic member 160a, the heat insulator 220, and the second elastic member 160b may be separate members stacked in the named order from above.

In the configuration according to this modification, the first elastic member 160a and the second elastic member 160b may be made of the same material, or may be made of different materials from each other. For example, since the temperature of the electrode plate 131 is generally higher than that of the base 100, the first elastic member 160a that comes into contact with the electrode plate 131 may be made of a metal, and the second elastic member 160b that comes into contact with the base 100 may be made of an elastomer.

With the configuration according to this modification, it is not necessary to join the heat insulator 220 to the base 100 or the electrode plate 131 by bonding, for example. Therefore, easy manufacture of the apparatus may be advantageously achieved, in addition to the effects described in the above embodiment.

In addition, in the above embodiments and modifications, the edge ring 180 is attracted and held by the edge ring electrostatic chuck 181, but the method of holding the edge ring 180 is not limited thereto. For example, the edge ring 180 may be attracted and held using an attraction sheet, or the edge ring 180 may be held by clamping. Alternatively, the edge ring 180 may be held by the weight thereof. In such a case, the edge ring electrostatic chuck 181 is omitted.

According to the present disclosure in some embodiments, it is possible to improve the temperature controllability within a high temperature region in a substrate support assembly that supports a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate support assembly comprising:
a base including a flow path for a temperature control medium formed therein;
a substrate support including an electrode plate installed on the base and an electrostatic chuck installed on the electrode plate, and configured to support a substrate;
a heater configured to heat the substrate;
an elastic member installed between the base and the electrode plate, configured to separate the substrate support from the base, and configured to define a heat transfer space between the base and the electrode plate together with the base and the electrode plate, a heat transfer gas being supplied into the heat transfer space;
a tightening member configured to fasten the base and the electrode plate to each other, with the elastic member sandwiched and supported between the base and the electrode plate; and
a heat insulator configured to prevent heat transfer between the base and the electrode plate via the elastic member.

2. The substrate support assembly of claim 1, wherein the heater is embedded in the electrostatic chuck.

3. The substrate support assembly of claim 1, wherein the heater is embedded in a temperature controller arranged on a lower surface of the electrode plate.

4. The substrate support assembly of claim 1, wherein the heat insulator has a thermal conductivity equal to or less than 20 W/mK.

5. The substrate support assembly of claim 1, wherein the heat insulator is made of a material including at least one selected from a group consisting of a titanium-containing material, stainless steel, alumina, yttria, zirconia, glass ceramics, and polyimide.

6. The substrate support assembly of claim 1, wherein the heat insulator is one or more layers of pressure-reduced spaces provided in at least one of the base and the electrode plate.

7. The substrate support assembly of claim 1, wherein the heat insulator includes a porous material and a coating material covering a surface of the porous material.

8. The substrate support assembly of claim 7, wherein the porous material includes an alumina oxide, a titanium oxide, or zirconia.

9. The substrate support assembly of claim 1, wherein the heat insulator is a porous material having a sealing layer on a surface thereof.

10. The substrate support assembly of claim 9, wherein the sealing layer has a thickness equal to or greater than 1 mm from the surface of the porous material.

11. The substrate support assembly of claim 1, wherein the heat insulator is installed between the electrode plate and the elastic member.

12. The substrate support assembly of claim 11, wherein the elastic member is made of an elastomer or a metal.

13. The substrate support assembly of claim 12, wherein the elastic member is made of at least one material selected from a group consisting of FFKM, FKM, silicone, aluminum, SUS, and an Ni-based superalloy.

14. The substrate support assembly of claim 1, wherein the heat insulator is installed between the base and the elastic member.

15. The substrate support assembly of claim 14, wherein the heat insulator is made of a metal.

16. The substrate support assembly of claim 1, wherein the tightening member and the base define a heat insulating space therebetween.

17. A plasma processing apparatus comprising:
a chamber having at least one gas supply port and at least one gas discharge port;
a substrate support assembly arranged in the chamber; and
a plasma generator coupled to the chamber,
wherein the substrate support assembly includes:
a base having a flow path for a temperature control medium formed therein;
a substrate support including an electrode plate installed on the base and an electrostatic chuck installed on the electrode plate, and configured to support a substrate;
a heater configured to heat the substrate;
an elastic member installed between the base and the electrode plate, configured to separate the substrate support from the base, and configured to define a heat transfer space between the base and the electrode plate together with the base and the electrode plate, a heat transfer gas being supplied into the heat transfer space;
a tightening member configured to fasten the base and the electrode plate to each other, with the elastic member sandwiched and supported between the base and the electrode plate; and
a heat insulator configured to prevent heat transfer between the base and the electrode plate via the elastic member.
